(19) United States
(12) Patent Application Publication
(10) Pub. No.: US 2010/0301677 A1
(43) Pub. Date: Dec. 2, 2010

(54) Photovoltaic Power Generation System and Photovoltaic Power Generation Device

(75) Inventor: Takashi TOMITA, Nara-shi (JP)

Correspondence Address: CROWELL & MORING LLP;INTELLECTUAL PROPERTY GROUP, P.O. BOX 14300, WASHINGTON, DC, 20044-4300, US

(73) Assignee: Smart Solar International Inc., Tokyo (JP)

(21) Appl. No.: 12/788,530

(22) Filed: May 27, 2010

(30) Foreign Application Priority Data
Jun. 1, 2009 (JP) 2009-132440

(51) Int. Cl. H02J 4/00; H01L 31/042; H01L 31/05; H01L 31/052

(52) U.S. Cl. 307/82; 136/244; 136/249; 136/246

(57) ABSTRACT

It is an object to obtain a photovoltaic power generation system. A photovoltaic power generation system includes multiple solar cell modules each having a different band gap and step-up voltage transformers (boosters) that receive outputs from load resistors, the load resistors being controlled to maximize outputs of the respective solar cell modules. An output voltage of each step-up voltage transformer (booster) is controlled to be a predetermined output voltage (or output current), and the step-up voltage transformers (boosters) are connected in parallel (or in series) to obtain predetermined electric power.

### BACKGROUND OF THE INVENTION

(1) Field of the Invention

The present invention relates to a photovoltaic power generation system and a photovoltaic power generation device.

(2) Description of the Related Art

Solar battery cells fall into two broad categories: one made of two kinds of semiconductors that form a p-n junction; and the other, which is called a dye-sensitized type cell, using dyes dispersed in ceramics. The solar battery of the present invention features both categories. It is known that the open-circuit voltage of a cell used in a solar battery is in general approximately 0.4 V lower than mainly the band gap width of the cell. In addition, the maximum electric power of the cell can be obtained by controlling the load impedance; however, the operating voltage is generally even lower than the open-circuit voltage. Thus, a solar battery requires multiple cells connected with each other in series. The multiple series-connected cells are generally referred to as a module.

Multiple solar cell modules are connected in series with each other to produce input voltage for an inverter. One of the indices to represent performance of solar batteries is conversion efficiency. A cell of a silicon semiconductor solar battery generally has conversion efficiency of approximately 14% to 23%, while a module has conversion efficiency of approximately 12% to 20%. Since the conversion efficiency of the solar cell and module have a direct effect on the system cost, efforts to improve conversion efficiency have been made. If light (photons), which corresponds to the band gap of a semiconductor, is irradiated to the semiconductor, efficiency of the light to be converted into energy, i.e., quantum efficiency (the ratio of photon energy to energy used to produce electrons and holes) is high, but light energy equal to or over the band gap is converted into heat in the semiconductor and therefore cannot be extracted as electric energy, resulting in a reduction of quantum efficiency. addition, since the spectrum of sunlight has a broad energy distribution ranging from ultraviolet to infrared, a single-gap semiconductor cannot handle the entire energy distribution.

### SUMMARY OF THE INVENTION

In order to substantially improve conversion efficiency, a method is used in which multiple semiconductors, each having a different band gap, are stacked on top of each other. This method uses semiconductors having high quantum efficiency in different wavelength bands and therefore prevents light energy from being consumed as heat energy. The use of a wide band-gap semiconductor naturally provides a high operating voltage, but operating current decreases by an amount corresponding to unused light energy. However, each semiconductor can obtain an operating current corresponding to its own p-n junction by maintaining the operating current constant, which improves conversion efficiency. Such a solar cell, which is generally referred to as a tandem cell or a triple cell, is an effective solution to extract wide-range light energy efficiently and can be expected to work effectively in any types of solar batteries.

There are some structures available for the above-described solar cell: for example, a gallium arsenide semiconductor stacked on a Ge substrate; and an indium gallium phosphide semiconductor stacked on a gallium arsenide semiconductor on a Ge substrate. The semiconductor cells may be fabricated by an MOCVD method, MBE method and so on. The tandem cells and triple cells are electrically connected to each other, respectively, with a tunnel junction.

The other examples of the cell include silicon-base thin film solar batteries. One of the developed batteries has a three-layered cell with p-n junctions made of amorphous silicon germanium, amorphous silicon and amorphous silicon carbide. The other has a stack of a micro-crystalline silicon p-n junction and an amorphous silicon p-n junction. A common feature of these cells/modules is that they are designed to be connected in series with each other, to electrically connect each p-n junction with a tunnel diode, and to maintain the current flowing between the cells constant.

As a method for improving efficiency, semiconductors each made of the same kinds of materials or different kinds of materials are stacked so as to utilize the band gaps of the semiconductors to ensure sensitivity suitable for the energy spectrum of sunlight; however, it is required to design the cells to maintain the current flow constant, otherwise the cells may suffer from a loss of power.

In order to fabricate such a highly efficient solar cell/module, semiconductors each having a different band gap need to be stacked. Realistically, it is not easy to stack the semiconductors each having a different band gap or, in other words, a different lattice constant. Actually, it is quite difficult to successfully stack the different kinds of semiconductors in fabrication steps of a tandem cell and triple cell because each semiconductor layer has its own lattice constant. In a case where a tandem type or triple type solar battery is made by stacking the aforementioned gallium arsenide semiconductor on the Ge substrate, the combination of Ge and GaAs can be relatively easily made because the lattice-constant mismatch between Ge and GaAs is small. On the contrary, combinations, such as Ge and silicon and silicon and gallium arsenide, in which the lattice constants significantly differ from each other, produce excessive strain and stress in both the semiconductor layers. The strain and stress cause a lattice defect in the semiconductor layers, resulting in serious reduction of conversion efficiency. Furthermore, the tunnel junction employed to electrically connect the cells requires formation of quite a high concentration of the semiconductor layer. Increasing the concentration of the semiconductors having a great band gap boosts the impurity level thereof, which hampers fabrication of an excellent tunnel diode.

Although amorphous silicon base semiconductors can be used as a method for improving conversion efficiency, general amorphous semiconductors have many lattice defects that cause recombination of electrons and holes excited by light, which reduces quantum efficiency. Even if the amorphous semiconductors are fabricated into a tandem type or triple type solar battery, the battery can never obtain conversion efficiency of more than 15%.

By the way, a technique of mechanically stacking semiconductors each having a different band gap has been proposed. In a case where two kinds of cells or modules are stacked, for example, the cells or modules are provided with two positive output terminals and two negative output terminals. Since the cells are different in voltage, current and load resistance, the cells require two pairs of outputs and two inverters. Increasing the number of the stacked solar batteries complicates wiring, which is difficult to achieve in fact. As described above, the voltage of the cell is approximately 0.5 to 1 V which is too low to be raised efficiently. Even step-up voltage transformers (boosters), which are often used in electric circuit technology, have difficulties in reducing power losses and improving conversion efficiency. Especially when an input voltage for the step-up voltage transformer (booster) is low, the power conversion efficiency of the step-up voltage transformers (booster) becomes low.

The present invention has been made in view of the above-described problems.

In order to reduce the power loss in the step-up voltage transformer (booster), the solar cells are connected in series so that a predetermined voltage is input to the step-up voltage transformer (booster), thereby increasing the operating voltage of the module to a predetermined value or more. The load resistor of the solar cell module is variably controlled so as to have a maximum power point tracking function. The output voltage of the module is set to a value suitable for improving the power efficiency of the step-up voltage transformer (booster).

Since the solar cells, each having a different band gap, are different from each other in terms of operating voltage, each solar cell module is set to output a voltage equivalent to a least common multiple of the operating voltage or a voltage equivalent to an integral multiple of the operating voltage.

The step-up voltage transformer (booster) includes a low-loss FET and circuit components (reactor, capacitor and diode). The step-up voltage transformers (boosters) are mutually feedback-controlled through data communication so that the output voltages of the step-up voltage transformers (boosters) become all the same. Simultaneously, the load resistors are controlled through the same data communication, thereby reducing the number of components.

The solar cell modules can be stacked on top of each other in a vertical direction regardless of their kinds, i.e., the lattice constant and band gap. Such solar cell modules can include a combination of semiconductors having high quantum efficiency in specific ranges of the solar spectrum and therefore enables efficient collection of sunlight energy from the entire spectrum ranges. The energy is converted into electric power and is input into the step-up voltage transformer (booster) through the load resistor with a maximum power point tracking function. The electric power can be efficiently extracted as output power at a predetermined voltage controlled by the step-up voltage transformer (booster). Each step-up voltage transformer (booster) is connected in parallel. Alternatively, the output currents from the step-up voltage transformers (boosters) are controlled to be constant, while the step-up voltage transformers (boosters) are connected in series to extract electric power.

The present invention can reduce output loss of each module in the course of power conversion and can combine the outputs from the modules. With this technique, it is possible to select solar batteries covering the solar spectrum, thereby dramatically enhancing power conversion efficiency.

According to the present invention, the cells can be easily stacked on top of each other regardless of the output current values of the cells, and, in addition, the outputs from each cell/module can be maximized and combined as electric power, thereby improving efficiency of the photovoltaic power generation.

Furthermore, according to the present invention, connection circuits included in the power generation system can be mounted on a single insulation board as a unit. Making the connection circuits into a unit facilitates assembly of the photovoltaic power generation system.

The present invention can improve stability of the connection circuits and reliability of cable connections.

### BRIEF DESCRIPTION OF THE DRAWINGS

Embodiments of the present invention will be described in detail based on the following figures, wherein:

FIG. 1 illustrates the concept of a photovoltaic power generation system in which two different kinds of cells are stacked on top of each other;

FIG. 2 is a wiring diagram of a module circuit;

FIG. 3 is a wiring diagram of a module circuit;

FIG. 4 is a wiring diagram of a module circuit;

FIG. 5 illustrates a photovoltaic power generation system;

FIG. 6 illustrates a photovoltaic power generation system with a cooling device;

FIG. 7 depicts a connection terminal unit board; and

FIG. 8 depicts a connection terminal unit board.

### DETAILED DESCRIPTION OF THE INVENTION

The photovoltaic power generation system of the present invention includes multiple solar cell modules each having a different band gap and step-up voltage transformers (boosters) that receive outputs from load resistors, the load resistors being controlled to maximize outputs of the respective solar cell modules. An output voltage of each step-up voltage transformer (booster) is controlled to be a predetermined voltage value, and the step-up voltage transformers (boosters) are connected in parallel to obtain predetermined electric power. The photovoltaic power generation system of the present invention includes multiple solar cell modules each having a different band gap and step-up voltage transformers (boosters) that receive outputs from load resistors, the load resistors being controlled to maximize outputs of the respective solar cell modules. An output current of each step-up voltage transformer (booster) is controlled to be a predetermined current value, and the step-up voltage transformers (boosters) are connected in series to obtain predetermined electric power.

In the photovoltaic power generation system according to the present invention, the solar cell module includes one or more solar cells, the solar cells being monolithic series-connected solar cells and being integrated and controlled to obtain a predetermined output voltage value, and each solar cell module is provided with a load resistor and a step-up voltage transformer (booster).

In the photovoltaic power generation system according to the present invention, the solar cell module includes one or more solar cells, the cells being monolithic series-connected solar cells and being integrated and controlled to obtain a predetermined output current value, and each module is provided with a load resistor and a step-up voltage transformer (booster).

In the photovoltaic power generation system according to the present invention, the solar cell module includes one or more solar cells, the cells being monolithic series-connected solar cells and being integrated and controlled to obtain a predetermined output voltage value, and each cell of each module is provided with a load resistor and a step-up voltage transformer (booster) formed in one piece with the cell.

In the photovoltaic power generation system of the present invention, the solar cell module includes one or more solar cells, the cells being monolithic series-connected solar cells, being integrated and controlled to obtain a predetermined output current, and each cell of each module is provided with a load resistor and a step-up voltage transformer (booster) formed in one piece with the cell.

The photovoltaic power generation system of the present invention further includes a step-down voltage transformer in addition to the load resistor and the step-up voltage transformer (booster).

The photovoltaic power generation system of the present invention further includes a step-down voltage transformer circuit in addition to the load resistor and the step-up voltage transformer (booster).

In the photovoltaic power generation system of the present invention, the solar cell module is irradiated with collected light.

In the photovoltaic power generation system of the present invention, the solar cell module and the step-up voltage transformers (boosters) are disposed in a cooling device.

The photovoltaic power generation system of the present invention further includes a control device that feeds back the output voltage or output current of the step-up voltage transformer (booster) and a communication device that conveys necessary information, and the step-up voltage transformer (booster) has a control function for controlling load impedance so as to maximize the output power of the solar cells.

In the photovoltaic power generation system of the present invention, the solar cell module and step-up voltage transformers (boosters) are placed in the cooling device, and the cooling device includes a coolant in conduits and is provided with a radiator.

In the photovoltaic power generation system of the present invention, each solar cell module is compressed by an optically transparent insulator, and the module, load resistor and step-up voltage transformers (boosters) are disposed on the insulator with wires.

A photovoltaic power generation device of the present invention includes multiple solar cell modules each having a different band gap, load resistors that are controlled to maximize outputs of the respective solar cell modules, and step-up voltage transformers (boosters) that increase output voltages. The output voltage of each step-up voltage transformer (booster) is controlled to be a predetermined voltage value, and the step-up voltage transformers (boosters) are connected in parallel to obtain predetermined electric power.

A photovoltaic power generation device of the present invention includes multiple solar cell modules each having a different band gap, load resistors that are controlled to maximize outputs of the respective solar cell modules, and step-up voltage transformers (boosters) that increase output voltages, wherein an output current of each step-up voltage transformer (booster) is controlled to be a predetermined current value, and the step-up voltage transformers (boosters) are connected in series to obtain predetermined electric power.

In the photovoltaic power generation system of the present invention, the solar cell module includes a p-n junction cell.

In the photovoltaic power generation system of the present invention, the solar cell module includes silicon and silicon carbide.

In the photovoltaic power generation system of the present invention, the solar cell module includes silicon and amorphous silicon.

In the photovoltaic power generation system of the present invention, the solar cell module includes amorphous silicon and germanium.

In the photovoltaic power generation system of the present invention, the solar cell module includes a dye-sensitized cell.

In a photovoltaic power generation device that includes load resistors that are controlled to maximize outputs of solar cell modules and step-up voltage transformers (boosters) that increase output voltages, the output voltage of the step-up voltage transformers (boosters) being controlled to be a predetermined voltage value and the step-up voltage transformers (boosters) being connected in parallel to obtain predetermined electric power, a connection unit board for the solar cell modules of the present invention includes at least two pairs of the load resistor and step-up voltage transformer (booster).

In a photovoltaic power generation device that includes load resistors that are controlled to maximize outputs of solar cell modules and step-up voltage transformers (boosters) that increase output voltages, an output current of the step-up voltage transformer (booster) being controlled to be a predetermined current value and the step-up voltage transformers (boosters) are connected in series to obtain predetermined electric power, a connection unit board for the solar cell modules of the present invention includes at least two pairs of the load resistor and step-up voltage transformer (booster).

The connection unit board for the solar cell modules of the present invention further includes a step-down voltage transformer in addition to the load resistor and the step-up voltage transformer (booster).

The connection unit board for the solar cell modules of the present invention further includes a step-down voltage transformer in addition to the load resistor and the step-up voltage transformers (boosters).

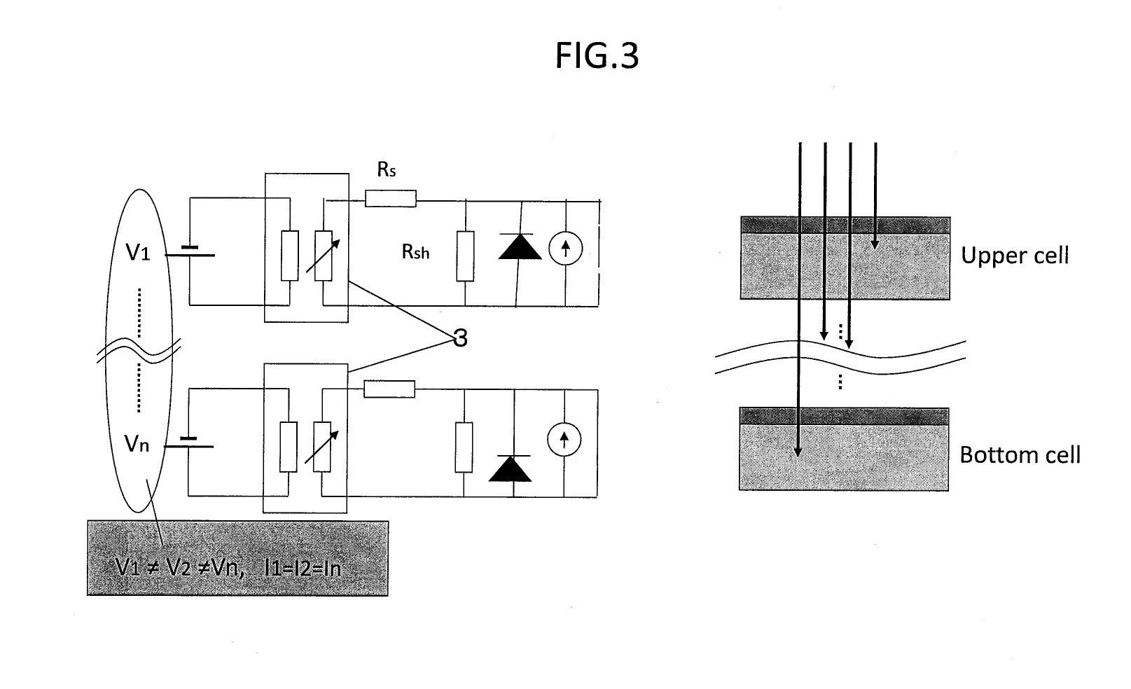

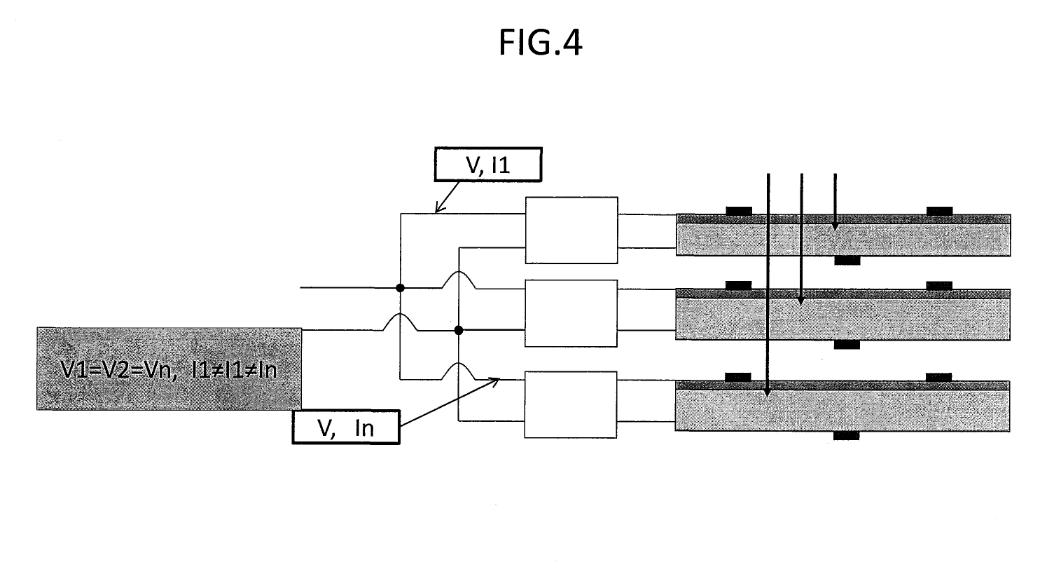

FIG. 3 shows a wiring diagram of module circuits according to the present invention. Multiple solar cells each having a different band gap are arranged from the front side in decreasing order of the band gap width. Each solar cell is designed to output its maximum power in accordance with the solar energy by controlling a load resistor. FIG. 3 shows load resistors 3 that are controlled to maintain the current constant. The voltages from the load resistors are different from each other. Since the voltages are connected in series, the voltages are added at a terminal (current control method). FIG. 4 shows load resistors that are controlled to maintain the voltage constant. The currents from the load resistors are different from each other. Since the currents are connected in parallel, the currents are added at a terminal (voltage control method).

If necessary, a step-down voltage transformer circuit is provided in the circuit.

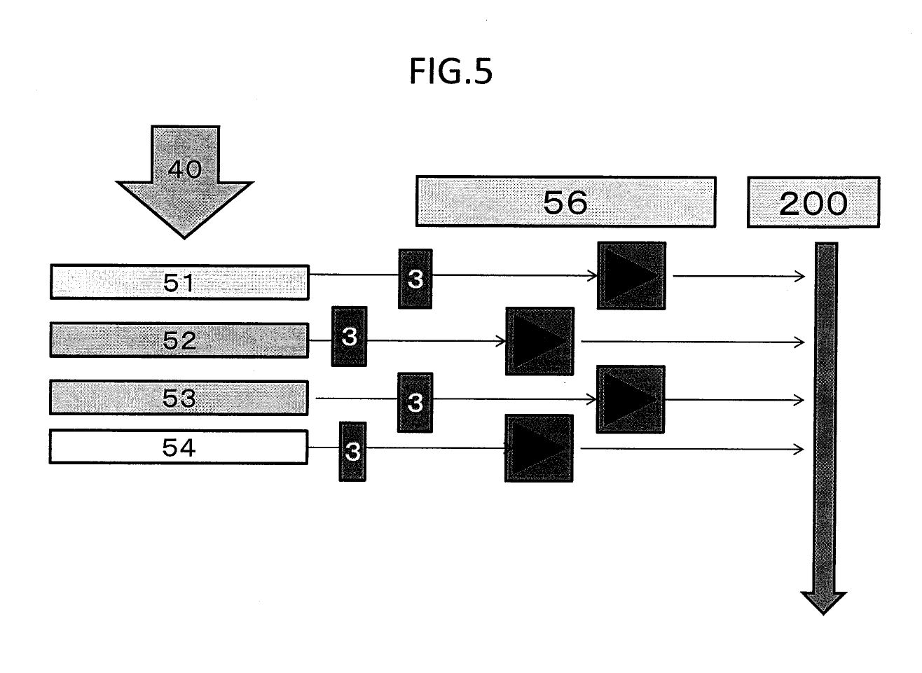

FIG. 5 illustrates a photovoltaic power generation system according to the present invention. Outputs that are produced by solar cell modules 51, 52, 53, 54 upon receipt of light 40 pass through respective load resistors 3 and high efficient converters 56 where the voltage of the outputs is controlled and are subsequently extracted. The high efficient converters 56 are controlled to output at the same voltage. Of course, the outputs from the converters are different, but have the same voltage, which means the output currents are different. The converters are connected in parallel. Alternatively, through the current control method, the high efficient converters 56 can be controlled to output the same current and connected in series to add voltages. The electric power is supplied to a transmission line 200. If necessary, a step-down voltage transformer circuit is provided in the circuit.

For the purpose of maximizing the conversion efficiency of the step-up voltage transformer (booster), the same kinds of solar cells are arranged in series so that input voltages of step-up voltage transformers (boosters) reach a predetermined value or more and the operating voltage of the modules is set to a predetermined value or more. Since the solar cells, each having a different band gap, are different from each other in terms of the operating voltage, each solar cell module is set to output a voltage equivalent to a least common multiple of the operating voltage or a voltage equivalent to an integral multiple of the operating voltage.

A solar cell module can output its maximum electric power by controlling the load resistor; however, the output voltage of the module is controlled appropriately so as to enhance the conversion efficiency of the step-up voltage transformer (booster). The step-up voltage transformer (booster) includes a low-loss FET and circuit components (reactor, capacitor and diode). The step-up voltage transformers (boosters) are mutually feedback-controlled through data communication by a communication IC chip so that the output voltages of the step-up voltage transformers (boosters) become all the same. Simultaneously, the load resistors are controlled through the same data communication, thereby reducing the number of components. Data communication can be performed through other routes including a power line by a power line communication technique, thereby simplifying wiring and fabrication work in array assembling. Stability of the output voltage can be ensured by mounting the load resistor, power detector, converter, communication IC chip, and back-flow prevention diode of the solar cell module on a single substrate.

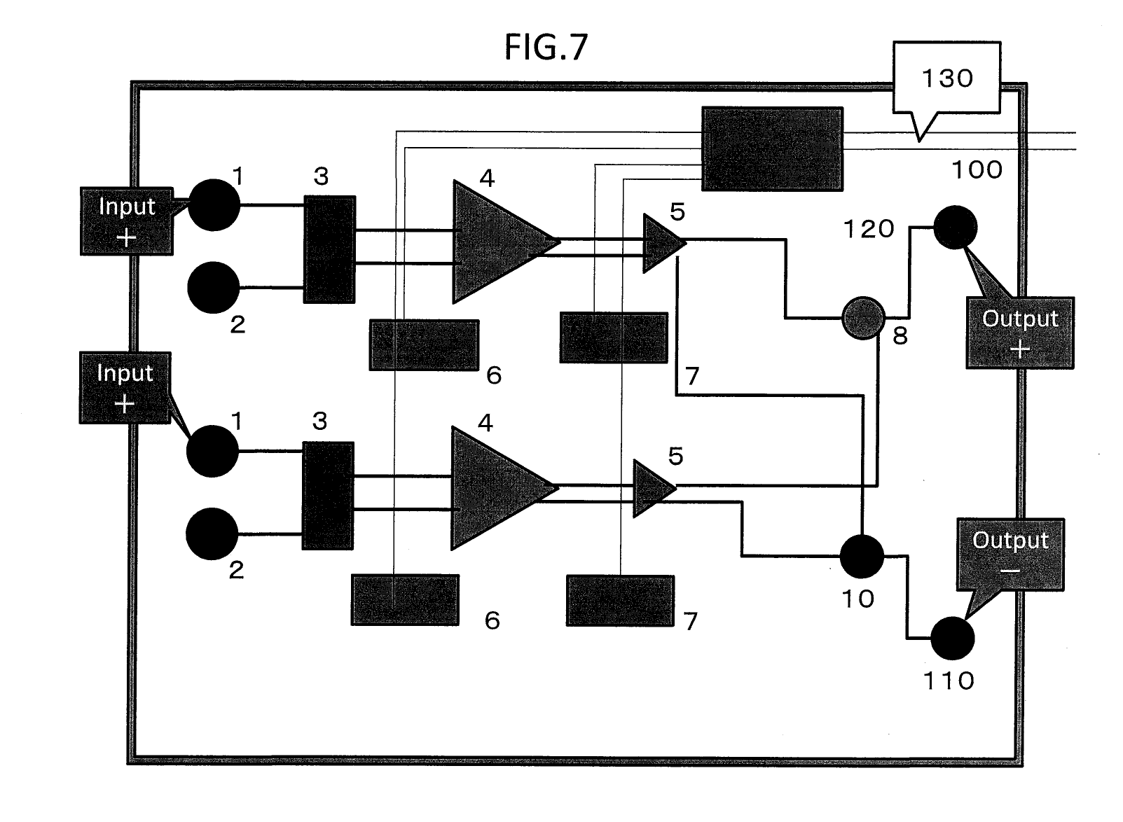

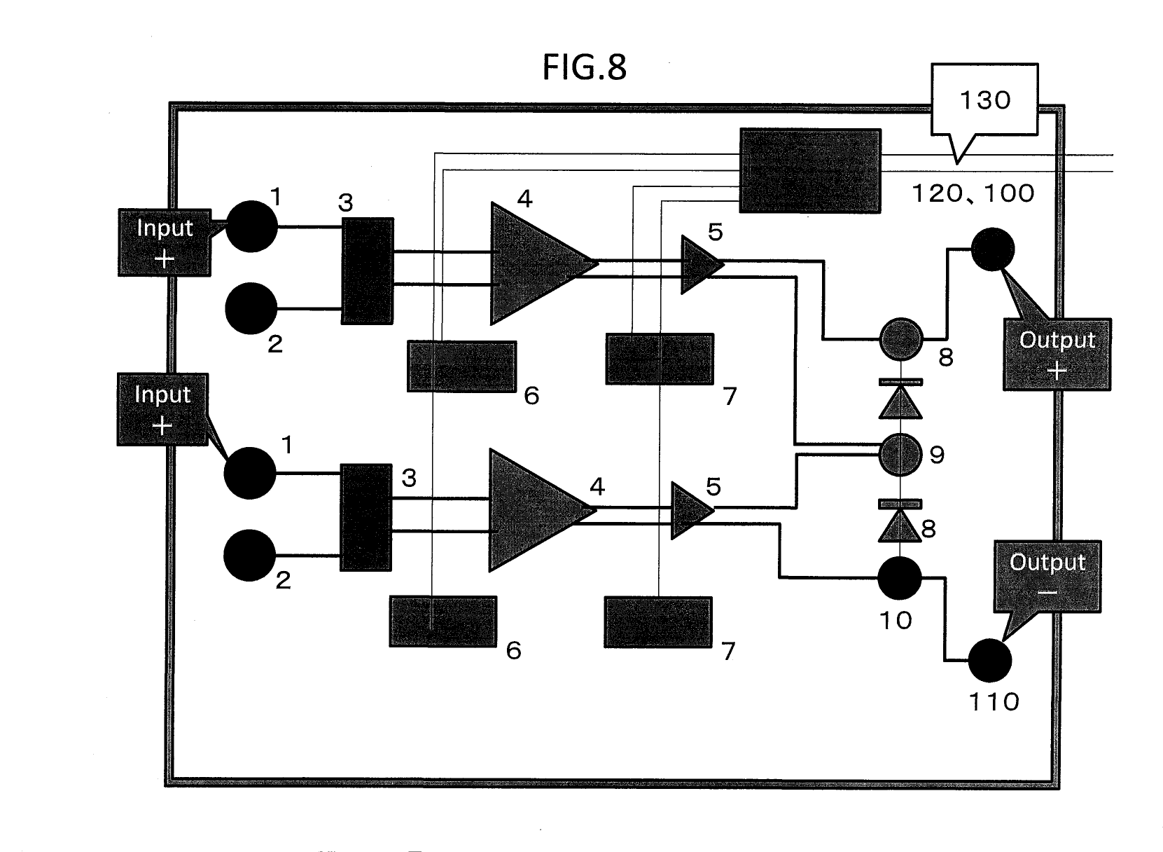

As shown in FIG. 8, each of the solar cell modules has output connecting terminals. Load resistors 3, power detectors 6, 7, converters, back-flow prevention circuits 5 are grouped in pairs and the pairs are defined as a unit. Multiple units are provided with output terminals 100 and 110 that are commonly shared by the units to extract electric power, thereby eliminating complexity of wiring. The unit is provided with input terminals 1 and 2 so that the number of inputs from the solar cell module can be increased from 2 to 5 and more. Alternatively, as shown in FIG. 7, the components are connected in parallel in a unit.

Since general FETs are made from semiconductors, such as silicon, GaN and SiC, the FET can be formed in a monolithic manner on the semiconductor included in the solar battery, thereby reducing manufacturing cost.

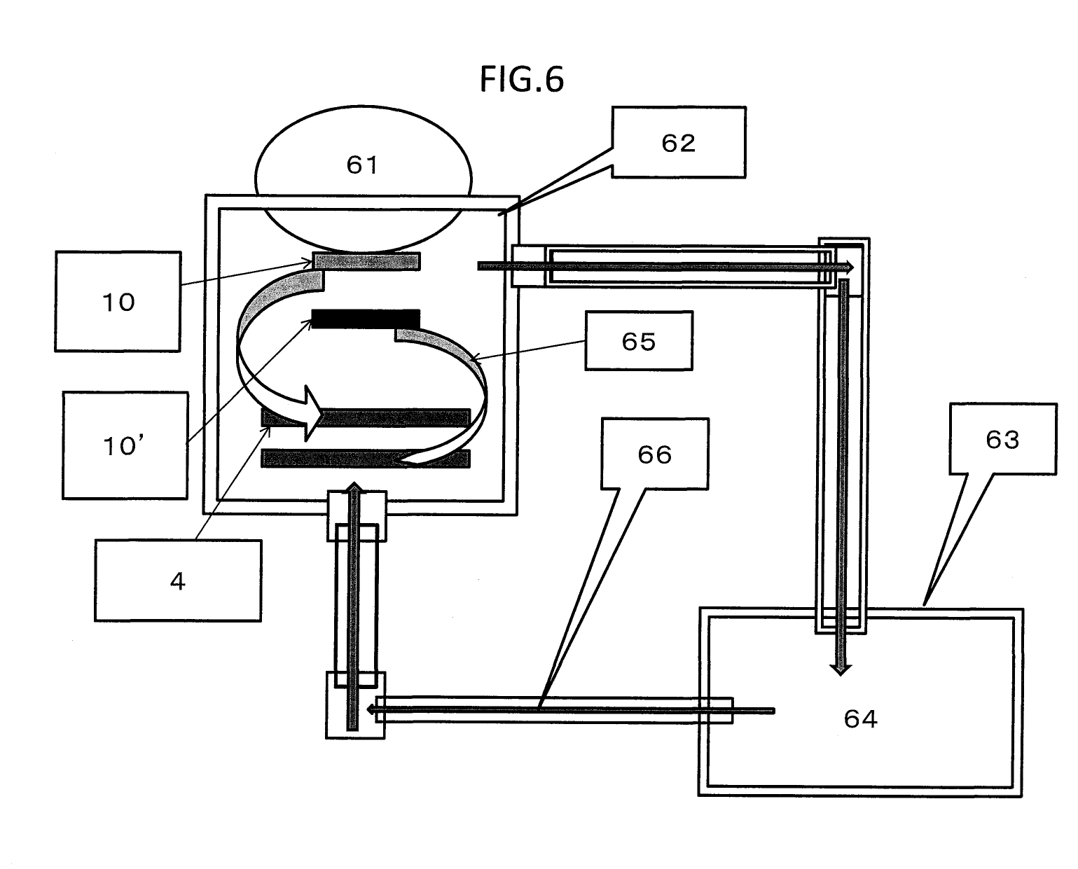

FIG. 6 shows a cooling device with a condenser according to the present invention. As shown in FIG. 6, the cooling device is provided with a condensing lens unit, multiple pairs of a solar battery and a step-up voltage transformer (booster). The solar batteries and step-up voltage transformers (boosters) are placed in the cooling unit filled with a coolant. The coolant is conveyed to a radiator that collects heat produced by the solar cell modules and step-up voltage transformers (boosters) and dissipates the heat. Even though an enormous amount of solar energy is collected by a lens or mirror, the cooling device can prevent reduction of the output of the solar battery due to the heat and can hold down rising temperature caused by the heat from the step-up voltage transformer (booster), thereby reducing losses and enhancing performance characteristics.

The solar cell modules of two kinds or more are vertically stacked on top of each other so that semiconductors each having high quantum efficiency in a specific region of the solar spectrum can be utilized in combination, thereby efficiently collecting energy from broad ranges of sunlight and combining electric power by controlling voltage and current. This eliminates the necessity of laminating semiconductors of two kinds or more on a single substrate as well as allows the selection of any kind of solar batteries according to desired light wavelengths. The energy from each solar battery is converted into electric power through the load resistor with a maximum power tracking function and the power is input to the step-up voltage transformer (booster). Even if the output of each solar battery varies with the solar illumination variation, the solar battery can obtain its maximum power according to the illumination variation. In the case where solar batteries of two kinds or more are stacked on top of each other, the maximum power can be obtained, as described above, by connecting the step-up voltage transformers (boosters) in parallel after controlling the output voltage to be a predetermined voltage value and combining the outputs or connecting the step-up voltage transformers (boosters) in series after controlling the output voltage to be a predetermined voltage and combining the outputs. This can reduce the output losses of each module in the course of power conversion and can readily combine the power. Since the solar module does not require a tunnel diode, thereby simplifying assembling processes and eliminating absorption loss of light caused by the tunnel diode. With these techniques, it is possible to select solar batteries covering the solar spectrum and therefore power conversion efficiency can be dramatically improved. In addition, the voltage increased upon transmission through a power line can reduce transmission losses.

As shown in FIG. 7, the input voltage for the step-up voltage transformer (booster) is supplied from the module after the number of the solar cells connected in series is controlled, thereby improving conversion efficiency of the step-up voltage transformer (booster). Placement of the solar cell module, load resistor, step-up voltage transformer (booster) and power detecting circuit on a transparent insulating substrate can simplify manufacturing processes and test processes. As shown in FIG. 8, a circuit, which includes the connecting terminals 1 and 2, load resistors 3, step-up voltage transformers (boosters) 4, back-flow prevention circuits 5, power detectors 6, 7 and connecting terminals 8, 9, 10, but not the solar cell module, is defined as a unit. The multiple units are combined on the substrate that is provided with output terminals 100, 110 and a communication IC chip 120 at the last stage, thereby simplifying manufacturing processes. A power line connected with the output terminals can be used as a communication line 130.

### EMBODIMENTS

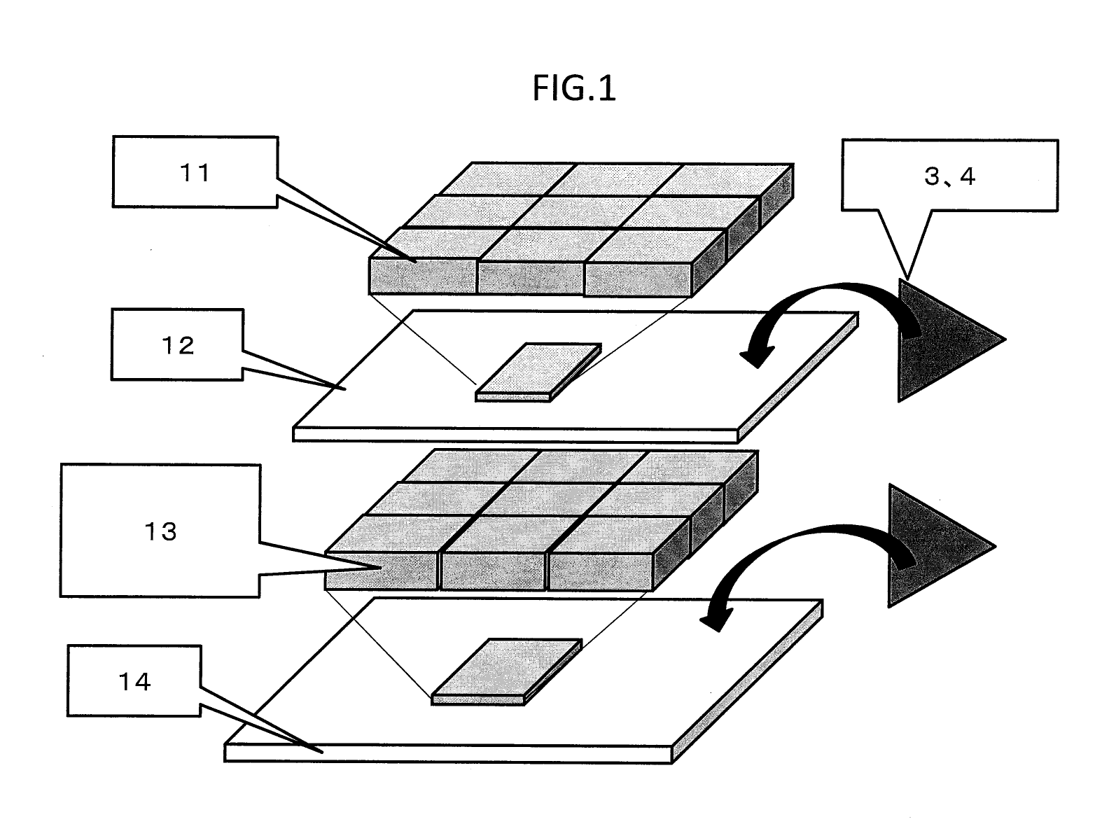

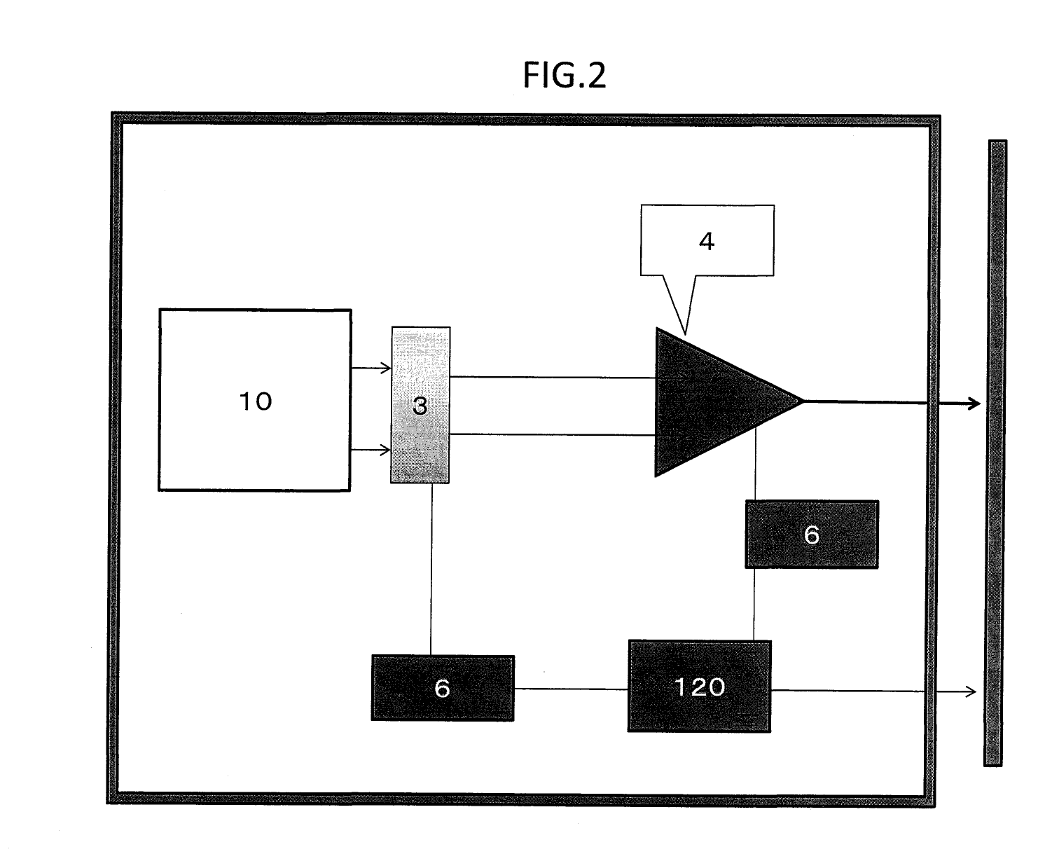

Embodiments of the present invention will be described with reference to FIGS. 1 to 8 below.

### Embodiment 1

FIG. 1 illustrates a basic concept of the photovoltaic power generation system according to Embodiment 1 of the present invention. Silicon and germanium, both crystallize in the diamond structure with a lattice constant of 0.543 nm and 0.565 nm, respectively, and that is to say, the silicon and germanium are lattice-mismatched semiconductor materials. Substrates employed for both the silicon and germanium are a single-crystalline <100> direction p-type substrate. The surface layer is doped to be an n-type diffused layer. A silver electrode is formed on a part of the front surface as an n-type electrode, while an aluminum electrode is formed on a part of the back surface as a p-type electrode. A germanium cell 13 is divided into 121 sections (11×11), each of which being connected in series with a transparent insulating substrate 14. Similarly, a silicon cell 11 is divided into 49 sections (7×7), each of which being connected in series with a transparent insulating quartz substrate 12. Before the cells are divided, each of them has an area of 1 cm²; however, the area of the cells does not limit the present invention.

The cell is connected to the substrate by welding a silver-plated copper tab. Each cell is wired to the transparent quartz substrate 12 with a wire partially made of titanium/silver. At the output of each cell, a load resistor with the power detector is placed to track the maximum power point. The reference numbers 3 and 4 in FIG. 1 denote the load resistor and step-up voltage transformer (booster) connected in a circuit, respectively.

The power detector transmits a signal through a communication chip to an external digital-signal processor to calculate a maximum power point that is used to control the impedance of the load resistor. The output of the load resistor is introduced to an input of the step-up voltage transformer (booster). The step-up voltage transformer (booster) 4 formed on the quartz substrate includes a silicon MOSFET with a small on-resistance, a reactor, a capacitor and a low resistance diode.

The output voltage of each step-up voltage transformer (booster) 4 is continuously monitored by the power detector and is controlled to be a predetermined voltage. Information from the power detector is processed into digital data through a communication IC chip mounted on the same substrate as that on which the power detector is placed and is fed back to the step-up voltage transformer (booster) and load resistor.

For the purpose of describing Embodiment 1, Table 1 shows data of a germanium cell, a silicon cell and a germanium cell under a silicon cell and modules thereof. Table 2 shows the same, but they are irradiated with light collected 300 times more than that in Table 1.

TABLE 1
Data of the solar cell module according
to Embodiment 1 (under 1 SUN, 100 mW/cm²)

| | kind of solar battery | | | | | |
|---|---|---|---|---|---|---|
| | Germanium cell | | silicon cell | | Germanium cell | |
| | (1 cm²) | | (1 cm²) | | under silicon cell | |
| single cell's open-circuit | 0.28 | V | 0.65 | V | 0.26 | V |
| voltage | | | | | | |
| single cell's short-circuit | 0.045 | A | 0.034 | A | 0.043 | A |
| current | | | | | | |
| single cell's fill factor | 0.65 | | 0.79 | | 0.64 | |
| single cell's operating voltage | 0.25 | V | 0.58 | V | 0.24 | V |
| single cell's operating current | 0.035 | A | 0.03 | A | 0.032 | A |
| module's open-circuit voltage | 33.88 | V | 31.9 | V | 31.46 | V |
| | (121 stages) | | (49 stages) | | | |
| module's short-circuit current | 0.00037 | A | 0.0007 | A | 0.00035 | A |
| module's fill factor | 0.65 | | 0.78 | | 0.61 | |
| module's operating voltage | 30.3 | V | 28.4 | V | 29.0 | V |
| module's operating current | 0.00029 | A | 0.00061 | A | 0.00026 | A |
| output power | 0.0088 | W | 0.0173 | W | 0.0075 | W |

TABLE 2
Results upon 300 times light collection

| | kind of solar battery | | | | | |
|---|---|---|---|---|---|---|
| | | | | | Germanium cell | |
| | Germanium cell | | silicon cell | | under silicon cell | |
| module's operating voltage | 31.8 | V | 29.8 | V | 30.5 | V |
| module's operating current | 0.096 | A | 0.183 | A | 0.086 | A |
| module output power | 3.05 | W | 5.45 | W | 2.62 | W |

| | | | | | |
|---|---|---|---|---|---|
| output power after step-up | — | 5.28 | W | 2.54 | W |
| voltage transformer (booster) | | | | | |

| | |
|---|---|
| combined output power | Output voltage and output current after step-up |
| | voltage transformer (booster): 375 V and 0.021 A |
| | Combined output power of silicon cell and germanium cell: 7.82 W |
| | Conversion efficiency: 97% |

To make the effect of Embodiment 1 easier to understand, Table 1 shows the open-circuit voltage, short-circuit current, fill factor, operating current and operating voltage of a germanium cell and module thereof. Table 2 shows the open-circuit voltage, short-circuit current, fill factor, operating current and operating voltage of a silicon module and germanium module to be placed under the silicon module, according to Embodiment 1 of the present invention, with light collected thereon.

Table 1 further shows the open-circuit voltage, short-circuit current, fill factor, operating current and operating voltage of a germanium cell that is stacked under a silicon cell. Table 2 also shows, when 300-times greater light is collected onto the stacked module, the operating voltage and operating current of the module, the output power of the module, the output power of the step-up voltage transformer (booster) and the characteristics of the module after the electric power of each module is combined, as a result of Embodiment 1 of the present invention. When the stack of silicon and germanium according to Embodiment 1 of the present invention was applied with 300-times greater light, the output power combined by the step-up voltage transformer (booster) was 7.82 W with an output voltage of 375 V and output current of 0.29 A. It is confirmed that the combined output power increased 48% more than the output power of 5.28 W of the single silicon cell. The conversion efficiency of the converter was 97%.

It is generally known that the step-up voltage transformer (booster) depends on input voltage and input power. In Embodiment 1, when the input voltage was 30 V and the input power was approximately 5 W to 10 W, the step-up voltage transformer (booster) obtained an output voltage of 375 V, that is, the power conversion efficiency was 97%. The combined output current was 0.29 A. The current from the respective outputs was 0.18 A and 0.086 A. It is of course possible to further enhance the power conversion efficiency by decreasing the on-resistance of the FET. Increasing the switching frequency of the FET of the step-up voltage transformer (booster) can decrease the capacitance of the reactor and capacitor. The switching frequency in Embodiment 1 is set to 50 kHz.

The step-up voltage transformer (booster) provided a voltage of 375 V. The respective step-up voltage transformers (boosters) are connected in parallel to each other and connected to a power line to provide electric power. Since the solar battery in Embodiment 1 uses silicon, a MOSFET that is made of a single-crystalline silicon can be formed on the solar battery substrate in a monolithic manner.

Making the MOSFET and solar battery monolithic can not only reduce their material cost, but also reduce the length of the circuit, which facilitate the design.

In Embodiment 1, each of the step-up voltage transformers (boosters) 4 formed on the quartz substrate includes a silicon MOSFET with a small on-resistance, a reactor, a capacitor and a low resistance diode. The output voltage of each step-up voltage transformer (booster) 4 is continuously monitored by the power detector 6 and is controlled to be a predetermined voltage. The output voltage of the step-up voltage transformer (booster) 4 in Embodiment 1 is set to 400 V. The respective step-up voltage transformers (boosters) are connected in parallel to each other and connected to a power line to provide electric power.

In addition to the step-up voltage transformer (booster), if necessary, a step-down voltage transformer circuit can be of course connected to the above-described structure.

Some solar cells/modules, like an amorphous silicon thin-film solar battery, sometimes easily produce greater outputs with a high operating voltage and a low operating current. For such a module, the step-down voltage transformer circuit may be required in addition to the step-up voltage transformer (booster).

### Embodiment 2

Silicon and gallium-aluminum arsenide (GaAlAs) have a lattice constant of 0.543 nm and 0.562 to 0.563 nm, respectively, which belong to a group in which an epitaxial growth technique cannot be used because it causes distortion. Table 3 shows the characteristics of cells per unit area and data of modules per 100 cm².

As a lower first cell, a silicon cell was used. An upper second cell was made of GaAlAs. The GaAlAs cell and silicon cell were mounted on a transparent insulating substrate such as a quartz, respectively, and stacked. The output of each cell was extracted at a load resistor and a step-up voltage transformer (booster). When light is irradiated at an air mass (AM) of 1.5 and current is maintained constant at 0.027 A, the output voltages of the output circuits are 17.4 V and 16.6 V, respectively. The voltages are combined in series, resulting in 40 V in total. The solar batteries are designed to change the output voltage with changes in illumination.

It is generally known that the spectrum of sunlight changes during the daytime. In a case of conventional stacked cells, if the current of each cell changes, the smallest current value is selected under the law of constant current and therefore the entire output of the modules becomes low. However, according to Embodiment 2 of the present invention, the maximum electric power can be extracted from each cell. Even if the spectrum changes, the maximum output power can be effectively extracted.

TABLE 3
Data of silicon cell and gallium-aluminum arsenide cell

| | kind of solar battery | | | | | |
|---|---|---|---|---|---|---|
| | silicon cell | | GaAlAs cell | | silicon cell | |
| | (4 cells in series) | | (2 cells in series) | | under GaAlAs cell | |
| single cell's open-circuit voltage | 0.65 | V | 1.12 | V | 0.63 | V |
| single cell's short-circuit current | 0.038 | A | 0.025 | A | 0.020 | A |
| single cell's fill factor | 0.78 | | 0.82 | | 0.73 | |
| single cell's operating voltage | 0.62 | V | 1.12 | V | 0.58 | V |
| single cell's operating current | 0.032 | A | 0.024 | A | 0.024 | A |
| module's open-circuit voltage | 2.6 | V | 2.24 | V | 2.5 | V |
| module's short-circuit current | 0.038 | A | 0.024 | A | 0.025 | A |
| module's fill factor | 0.76 | | 0.82 | | 0.7 | |
| module's operating voltage | 2.3 | V | 2.1 | V | 2.2 | V |
| module's operating current | 0.038 | A | 0.025 | A | 0.023 | A |

| | | | | | |
|---|---|---|---|---|---|
| output power | — | 0.0525 | W | 0.05 | W |

Output power: 0.109 W
Output voltage after step-up voltage transformer (booster) on low layer: 17.4 V, output current: 0.00271 A
Output voltage after step-up voltage transformer (booster) on upper layer: 16.6 V, output current: 0.00271 A
Output current: 0.00271 A, output voltage: 34 V

### Embodiment 3

When stacked solar cell modules are manufactured, a terminal box in which a connection terminal unit is installed is attached to every module. The wiring diagram of the connection terminal unit is shown in FIG. 7. An input from the solar cell module is introduced through terminals 1 and terminals 2. The terminals 1 have a higher potential than that of the terminals 2. The terminals 1 and 2 are connected to load resistors 3 and the inputs are fed to step-up voltage transformers (boosters) 4. Outputs from the step-up voltage transformers (boosters) 4 are introduced from back-flow prevention diodes 5 to connecting terminals 8 and 10 where the outputs are combined. The combined output power is extracted from output terminals 100 and 110. A communication IC chip 120 is connected to communication lines. Although there are two inputs in FIG. 7, it is needless to say that the number of the inputs can be increased to three, four or more. FIG. 8 shows a structure of a voltage-controllable connection unit.

FIG. 7 shows a current-controllable connection circuit, as shown in FIG. 3, for modules of the photovoltaic power generation system according to the present invention.

The connection circuit includes load resistors 3, step-up voltage transformers (boosters) 4, back-flow prevention circuits 5, power detectors 6, 7 and communication IC chips 120. The multiple connection circuits are connected in parallel to output electric power. In the present invention, the connection circuit is formed into a unit and mounted on a single insulation board. The insulation board is provided with output terminals 100 and 110 for the purpose of connection and stability of the circuit. Making the circuit into a unit can facilitate assembly of the power generation system. In addition, the unit can be formed in a terminal box, which is generally attached to the module. Such a module can increase its output voltage, thereby decreasing the diameter of power cables. The number of cables can be decreased by sending signals from the communication IC chip through power line communication using a pulse-duration modulation technique or the like. The reference number 130 denotes communication lines.

FIG. 8 shows a voltage-controllable connection circuit, as shown in FIG. 4, for modules of the photovoltaic power generation system according to the present invention.

The connection circuit includes load resistors 3, step-up voltage transformers (boosters) 4, back-flow prevention circuits 5, power detectors 6, 7 and a communication IC chip 120. The multiple connection circuits are connected in series to output electric power. In the present invention, the connection circuit is formed into a unit and mounted on a single insulation board. The insulation board is provided with output terminals 100 and 110. According to the structure, stability of the connection circuits and reliability of cable connection are secured. The reference number 130 denotes communication lines.

### Embodiment 4

FIG. 6 shows an example in which a cell module is installed in a cooling device.

With the module described in Embodiment 2, a solar concentrator with a cooling device is fabricated.

The module is housed in the cooling device 62. The device is filled with a coolant 64. Even if light condensed by a lens 61 boosts the temperature of the operating silicon cells and gallium-aluminum arsenide cells as shown in FIG. 6, the coolant instantaneously absorbs the heat of the cells and the heated coolant is conveyed through a conduit 66 to a radiator 63 where the coolant 64 is cooled. The coolant 64 is returned through the conduit 66 to a solar concentration section to cool the cells/modules again. This is especially effective for solar batteries with a small band gap to prevent output reduction caused by temperature.

In Embodiment 4, the step-up voltage transformer (booster) 4 is also cooled so as to realize high conversion efficiency. The step-up voltage transformer (booster) 4 and the cell/module 10 and 10′ are connected with flexible conducting lines 65. Although the coolant used in Embodiment 4 is ethanol, an aqueous solution, organic solvent, a chlorofluorocarbon and so on can be used. Consequently, the output current having passed through the step-up voltage transformer (booster) is 0.0035 A, while the output voltage is 375 V.

### Embodiment 5

The solar battery in Embodiment 5 includes a germanium cell, a silicon cell, an amorphous silicon carbide cell and a silicon carbide cell.

In Embodiment 5 of the present invention, multiple cells are stacked on top of each other. Since it is not necessary to maintain the current value of each cell constant, it is relatively easy to stack the cells. In embodiment 5, four cells, i.e., a germanium cell, a silicon cell, an amorphous silicon carbide cell and a silicon carbide cell, are used. With reference to spectral illumination of sunlight, the number of photons for each wavelength and the cumulative total thereof are calculated.

It is recommended to use semiconductors having as large a band gap as possible in order to achieve maximum output. In a conventional theory, when the currents flowing through cells are not constant, the smallest current value is used to determine the available current of the stacked module. Therefore, even if the other modules can provide more current, the current that exceeded the smallest current value cannot be extracted. The present invention can circumvent such a constraint and therefore can make it possible to select an industrially-useable solar cell with flexibility.

According to the present invention, the cells can be easily stacked in an appropriate manner for the number of kinds of cells used in the solar cell module regardless of the output current values of the cells, each cell/module can output its maximum power, and the electric power can be combined, thereby bringing high efficiency to the photovoltaic power generation. This specification describes mainly the semiconductor cells; however, the present invention is applicable to a stack of organic semiconductor type and dye-sensitized type solar batteries. It is needless to say that the present invention is effective to a stack of a semiconductor cell and dye-sensitized type cell.

Table 4 shows data of each cell per 1 cm² of Embodiment 5.

Table 4 shows data of each cell per 1 cm².

Table 5 shows characteristics and combined output of the modules in Embodiment 5.

TABLE 4
Data of each cell per 1 cm² of Embodiment 5

| | kind of solar battery | | | | | | | |
|---|---|---|---|---|---|---|---|---|
| | | | | | Amorphous silicon | | silicon | |
| | Germanium cell | | silicon cell | | carbide cell | | carbide cell | |
| single cell's open-circuit voltage | 0.25 | V | 0.65 | V | 1.2 | V | 1.6 | V |
| single cell's short-circuit current | 0.045 | A | 0.034 | A | 0.02 | A | 0.01 | A |
| single cell's fill factor | 0.65 | | 0.79 | | 0.75 | | 0.8 | |
| single cell's operating voltage | 0.25 | V | 0.58 | V | 1.0 | V | 1.3 | V |
| single cell's operating current | 0.035 | A | 0.03 | A | 0.018 | A | 0.007 | A |

TABLE 5
Characteristics and combined output power of modules in Embodiment 5

| | kind of solar battery | | | | | | | |
|---|---|---|---|---|---|---|---|---|
| | silicon carbide module, | | silicon carbide module, | | amorphous silicon | | | |
| | amorphous silicon carbide | | and silicon module under | | carbide module | | | |
| | module and Germanium module | | amorphous silicon | | under silicon | | silicon | |
| | under silicon module | | carbide module | | carbide module | | carbide module | |
| module area | 100 | | 100 | | 100 | | 100 | |
| number of module stages | 100 | | 64 | | 25 | | 49 | |
| module's open-circuit voltage | 25 | V | 41.6 | V | 30 | V | 78.4 | V |
| module's short-circuit current | 2.5 | A | 3.6 | A | 1.8 | A | 1.5 | A |
| module's fill factor | 0.6 | | 0.75 | | 0.65 | | 0.75 | |
| module's operating voltage | 22.5 | V | 39.4 | V | 27.0 | V | 73.6 | V |
| module's operating current | 2.3 | A | 3.3 | A | 1.6 | A | 1.3 | A |
| output power | 51.75 | W | 130.02 | W | 43.2 | W | 95.68 | W |

Output power after step-up voltage transformer (booster) of stacked module: 304.6 W
Output voltage after step-up voltage transformer (booster): 375 V
Germanium module: 0.13 A
Silicon module: 0.33 A
Amorphous silicon carbide: 0.11 A
Silicon carbide cell: 0.24 A
Total output power after step-up voltage transformer (booster): 0.81 A

This specification describes mainly semiconductor cells; however, organic semiconductor type and dye-sensitized type solar batteries can be also stacked in the same manner and those batteries are effective. The semiconductor cell and dye-sensitized type cell can be also stacked in the same manner and the batteries are effective.

According to the above-described present invention, the cells can be easily stacked regardless of the output current values of the cells, each cell/module can output its maximum power, and the electric power can be combined, thereby bringing high efficiency to the photovoltaic power generation.

In the present invention, each connection circuit included in the generation system is formed into a unit and mounted on a single insulation board. Making the circuit into a unit can facilitate assembly of the photovoltaic power generation system.

Some solar cells/modules, like an amorphous silicon thin-film solar battery, sometimes easily produce greater outputs with a high operating voltage and a low operating current. For such a module, the step-down voltage transformer circuit may be required in addition to the step-up voltage transformer (booster).

It should be understood by those skilled in the art that various modifications, combinations, sub-combinations and alterations may occur depending on design requirements and other factors insofar as they are within the scope of the appended claims or the equivalents thereof.

1. A photovoltaic power generation system comprising:
a plurality of solar cell modules each having a different band gap; and
step-up voltage transformers (boosters) that receive outputs from load resistors, the load resistors being controlled to maximize outputs of the respective solar cell modules,
wherein an output voltage of each step-up voltage transformer (booster) is controlled to be a predetermined voltage value, and
wherein the step-up voltage transformers (boosters) are connected in parallel to obtain predetermined electric power.

2. A photovoltaic power generation system comprising:
a plurality of solar cell modules each having a different band gap; and
step-up voltage transformers (boosters) that receive outputs from load resistors, the load resistors being controlled to maximize outputs of the respective solar cell modules,
wherein an output current of each step-up voltage transformer (booster) is controlled to be a predetermined current value, and
wherein the step-up voltage transformers (boosters) are connected in series to obtain predetermined electric power.

3. The photovoltaic power generation system according to claim 1,
wherein the solar cell module includes one or more solar cells, the solar cells being monolithic series-connected solar cells, being integrated and controlled to obtain a predetermined output voltage value, and
wherein each solar cell module is provided with a load resistor and a step-up voltage transformer (booster).

4. The photovoltaic power generation system according to claim 2,
wherein the solar cell module includes one or more solar cells, the solar cells being monolithic series-connected solar cells, being integrated and controlled to obtain a predetermined output current value, and
wherein each solar cell module is provided with a load resistor and a step-up voltage transformer (booster).

5. The photovoltaic power generation system according to claim 3,
wherein the solar cell module includes one or more solar cells, the solar cells being monolithic series-connected solar cells, being integrated and controlled to obtain a predetermined output voltage value, and
wherein each cell of each module is provided with a load resistor and a step-up voltage transformer (booster) formed in one piece with the cell.

6. The photovoltaic power generation system according to claim 4,
wherein the solar cell module includes one or more solar cells, the solar cells being monolithic series-connected solar cells, being integrated and controlled to obtain a predetermined output current value, and
wherein each cell of each module is provided with a load resistor and a step-up voltage transformer (booster) formed in one piece with the cell.

7. The photovoltaic power generation system according to claim 1 further comprising:
step-down voltage transformers in addition to the load resistors and the step-up voltage transformers (boosters).

8. The photovoltaic power generation system according to claim 2 further comprising:
step-down voltage transformer circuits in addition to the load resistors and the step-up voltage transformers (boosters).

9. The photovoltaic power generation system according to claim 1, wherein the solar cell modules are irradiated with collected light.

10. The photovoltaic power generation system according to claim 1, wherein the solar cell modules and the step-up voltage transformers (boosters) are disposed in a cooling device.

11. The photovoltaic power generation system according to claim 1, further comprising:
a control device that feeds back the output voltage or output current of the step-up voltage transformer (boosters); and
a communication device that conveys necessary information,
wherein the step-up voltage transformer (booster) has a control function for controlling load impedance so as to maximize the output power of the solar cells.

12. The photovoltaic power generation system according to claim 1,
wherein the solar cell modules and step-up voltage transformers (boosters) are placed in the cooling device, and
wherein the cooling device includes a coolant in conduits and is provided with a radiator.

13. The photovoltaic power generation system according to claim 1,
wherein each solar cell module is compressed by an optically transparent insulator, and
wherein the module, load resistor and step-up voltage transformers (boosters) are disposed on the insulator with wires.

14. A photovoltaic power generation device comprising:
a plurality of solar cell modules each having a different band gap;
load resistors that are controlled to maximize outputs of the respective solar cell modules; and
step-up voltage transformers (boosters) that increase output voltages,
wherein an output voltage of each step-up voltage transformer (booster) is controlled to be a predetermined voltage value, and
wherein the step-up voltage transformers (boosters) are connected in parallel to obtain predetermined electric power.

15. A photovoltaic power generation device comprising:
a plurality of solar cell modules each having a different band gap;
load resistors that are controlled to maximize outputs of the respective solar cell modules; and
step-up voltage transformers (boosters) that increase output voltages,
wherein an output current of each step-up voltage transformer (booster) is controlled to be a predetermined current value, and
wherein the step-up voltage transformers (boosters) are connected in series to obtain predetermined electric power.

16. The photovoltaic power generation system according to claim 1, wherein the solar cell module includes a p-n junction cell.

17. The photovoltaic power generation system according to claim 16, wherein the solar cell module includes silicon and silicon carbide.

18. The photovoltaic power generation system according to claim 16, wherein the solar cell module includes silicon and amorphous silicon.

19. The photovoltaic power generation system according to claim 16, wherein the solar cell module includes amorphous silicon and germanium.

20. The photovoltaic power generation system according to claim 1, wherein the solar cell module includes a dye-sensitized cell.

21. A connection unit board for the solar cell module in a photovoltaic power generation device that includes load resistors that are controlled to maximize outputs of solar cell modules and step-up voltage transformers (boosters) that increase output voltages, an output voltage of each step-up voltage transformer (booster) being controlled to be a predetermined voltage value and the step-up voltage transformers (boosters) being connected in parallel to obtain predetermined electric power,
the connection unit board for the solar cell module comprising at least two pairs of the load resistor and step-up voltage transformer (booster).

22. A connection unit board for the solar cell module in a photovoltaic power generation device that includes load resistors that are controlled to maximize outputs of solar cell modules and step-up voltage transformers (boosters) that increase output voltages, an output current of each step-up voltage transformer (booster) being controlled to be a predetermined current value and the step-up voltage transformers (boosters) are connected in series to obtain predetermined electric power,
the connection unit board for the solar cell module comprising at least two pairs of the load resistor and step-up voltage transformer (booster).

23. The connection unit board for solar cell module according to claim 21 further comprising:
a step-down voltage transformer in addition to the load resistor and the step-up voltage transformer (booster).

24. The connection unit board for solar cell module according to claim 22 further comprising:
a step-down voltage transformer in addition to the load resistor and the step-up voltage transformer (booster).
